(19) United States
(12) Patent Application Publication
(10) Pub. No.: US 2022/0209750 A1
(43) Pub. Date: Jun. 30, 2022

(54) QUALITY FACTOR OF A PARASITIC CAPACITANCE

(71) Applicant: TEXAS INSTRUMENTS INCORPORATED, Dallas, TX (US)

(72) Inventors: Swaminathan Sankaran, Allen, TX (US); Brad Kramer, Plano, TX (US); Thomas Dyer Bonifield, Dallas, TX (US)

(21) Appl. No.: 17/223,792

(22) Filed: Apr. 6, 2021

Related U.S. Application Data
(60) Provisional application No. 63/131,405, filed on Dec. 29, 2020.

(51) Int. Cl. H03H 11/02; H01L 27/01; H01L 27/06

(52) U.S. Cl. CPC H03H 11/02; H01L 27/0682; H01L 27/013

(57) ABSTRACT

An integrated circuit includes a substrate, a reference contact coupled to the substrate, a capacitor over the substrate, and a substrate element. The capacitor includes a first conductive element having an associated parasitic capacitance and a second conductive element electrically isolated from the first conductive element. The substrate element is coupled to the first conductive element by the parasitic capacitance and coupled to the reference contact. The substrate element includes a conductive doped region in the substrate and aligned with the first conductive element and the reference contact.

### CROSS REFERENCE TO RELATED APPLICATIONS

This application claims priority to U.S. Provisional Patent Application No. 63/131,405 filed Dec. 29, 2020, which is incorporated herein by reference.

### TECHNICAL FIELD

This relates generally to integrated circuits, and more particularly to techniques for improving the quality factor of parasitic capacitance within an integrated circuit.

### BACKGROUND

Isolation is often desirable for interconnecting electrical systems to exchange data or power between the systems. For example, two systems may be powered by different supply sources that do not share a common ground connection. The two systems may be electrically isolated to prevent current and voltages in one system from negatively impacting the other system, for instance by damaging or interfering with the operation of one or more components of the other system. One form of isolation uses one or more capacitors to provide electrical isolation and to capacitively couple a data signal between the systems. However, capacitor-based isolation solutions often include parasitic capacitance that absorbs signal energy and results in significant signal-path attenuation due to bottom-plate parasitic capacitance that shunts signal energy to a local ground. More particularly, the fabrication of some existing capacitor-based isolation solutions on top of a substrate, such as a semiconductor substrate, produces a parasitic capacitance and series resistance between a bottom plate of an isolation capacitor and a reference terminal, such as ground, which limits the operating frequency for data communications using the isolation capacitor. This leads to poor power efficiency, and large amounts of parasitic capacitance can severely limit bandwidth, leading to limitations in data rates and increased data latency.

### SUMMARY

Described examples add a substrate element to the substrate. The substrate element includes one or more conductive doped regions of the substrate that overlaps the reference terminal and the bottom plate of the isolation capacitor. The one or more conductive doped regions provides a conductive path from the bottom plate of the isolation capacitor to the reference terminal, which reduces the series resistance associated with the parasitic capacitance, and thereby, improves the quality factor associated with the parasitic capacitance. The improved quality factor reduces dissipative loss through the parasitic capacitance to enable data communications at higher frequencies using the isolation capacitor. Additionally, in described examples, the substrate element is added during the front-end-of-line (“FEOL”) portion or segment of an integrated circuit (“IC”) fabrication process, which limits the impact on the isolation rating of the isolation capacitor.

In one example, an integrated circuit includes a substrate, a reference contact coupled to the substrate, a capacitor over the substrate, and a substrate element. The capacitor includes a first conductive element having an associated parasitic capacitance and a second conductive element electrically isolated from the first conductive element. The substrate element is coupled to the first conductive element by the parasitic capacitance and coupled to the reference contact. The substrate element includes a conductive region in the substrate and aligned with the first conductive element and the reference contact.

In another example, a system includes isolation circuitry including a semiconductor substrate, a reference contact coupled to the semiconductor substrate, an isolation capacitor over the semiconductor substrate, and a conductive doped region in the semiconductor substrate. The isolation capacitor includes a first conductive element having an associated parasitic capacitance and a second conductive element galvanically isolated from the first conductive element. The conductive region is aligned with the first conductive element and the reference contact.

In another example, a method of making an integrated circuit includes forming, in a substrate, a substrate element having a conductive doped region. The method further includes forming, on the substrate, a reference contact that is aligned with and mechanically coupled to the substrate element. The method also includes forming, over the substrate and aligned with the conductive doped region, a capacitor having first and second electrically isolated conductive elements, the first conductive element having an associated parasitic capacitance.

### BRIEF DESCRIPTION OF THE DRAWINGS

FIG. 1 is a schematic diagram of an example isolation system having multiple substrate elements.

FIG. 2 is a partial cross-sectional view of an example integrated circuit having a substrate element.

FIG. 3 is a partial cross-sectional view of another example integrated circuit having a substrate element.

FIG. 4 is a partial cross-sectional view of another example integrated circuit having a substrate element.

FIG. 5 is a partial cross-sectional view of another example integrated circuit having a substrate element.

FIG. 6 is a graphical representation illustrating the quality factor associated with a parasitic capacitance, which is improved by including a substrate element according to one or more examples.

FIG. 7 is a partial plan view of the example integrated circuit of FIG. 2.

FIG. 8 is a partial plan view of an example substrate element having a patterned region.

FIG. 9 is a schematic diagram of an isolation module incorporating the isolation system of FIG. 1.

FIG. 10 is a perspective view of a system incorporating the isolation module of FIG. 9.

FIG. 11 is a flowchart of an example method for making an integrated circuit having a substrate element.

FIG. 12 is a flowchart of another example method for making an integrated circuit having a substrate element.

FIG. 13 is a flowchart of another example method for making an integrated circuit having a substrate element.

### DETAILED DESCRIPTION OF EXAMPLE EMBODIMENTS

In the drawings, like reference numerals refer to like elements throughout, and the various features are not necessarily drawn to scale. In the description and in the claims, the terms “couple”, “coupled” or “couples” means an indirect or direct electrical or mechanical connection.

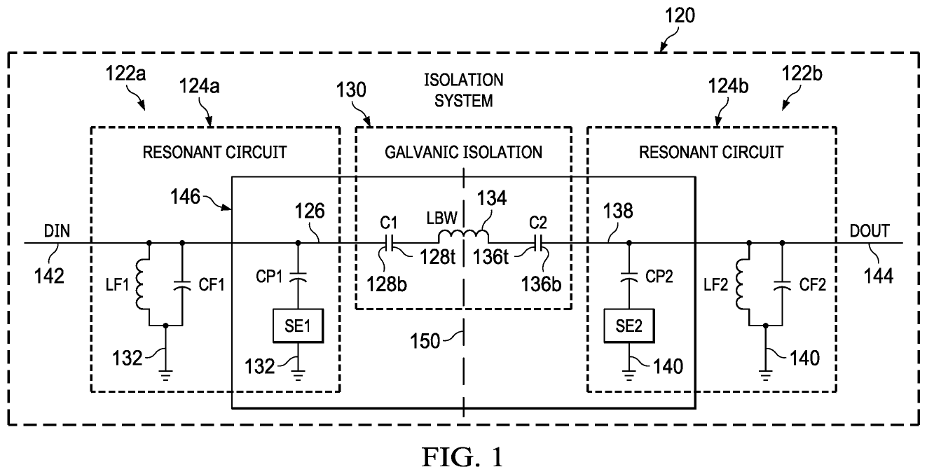

Referring initially to FIG. 1, which is a schematic diagram representing an example isolation system 120 having multiple substrate elements SE1 and SE2. In an example, system 120 is an equivalent circuit for one or more integrated circuits of a module within a larger system such as an isolated low-voltage differential signaling system of an isolated high-speed/full-speed Universal Serial Bus system. Isolation system 120 includes isolation and resonance circuitry 122a and 122b coupled together by an interconnect 134. Interconnect 134 is represented as an inductance LBW. In one example, interconnect 134 is a bond wire. In another example, interconnect 134 is patterned metal. The system 120 may provide a bandpass or multi-order filter network for employing in digital isolators or other isolation applications to convey a digital signal across a galvanic isolation barrier.

Isolation and resonance circuitry 122a includes a coupling or isolation capacitor C1, a substrate element SE1, and a coil that is illustrated as a filter inductor LF1. In an alternative example, the isolation and resonance circuitry 122a includes LF1 and also includes a filter capacitor CF1 coupled together in parallel. In a further example, the coil is implemented as a transformer instead of the inductor LF1, with or without the inclusion of CF1. In yet another example, LF1 is implemented as a transmission line, with or without the inclusion of CF1.

The capacitor C1 includes a conductive element referred to as a top plate 128t and a conductive element referred to as a bottom plate 128b. The bottom plate 128b of capacitor C1 has an associated parasitic capacitance CP1, and the top plate 128t is electrically isolated from the bottom plate 128b of capacitor C1.

As illustrated, the top plate 128t of capacitor C1 is coupled to one end of the interconnect 134, and the bottom plate 128b of capacitor C1 is coupled to a node 126. Node 126 may represent a connection to other circuitry outside of the system 120, such as a transmit circuit for sending a data signal. Substrate element SE1 is coupled to the bottom plate 128b of capacitor C1 by parasitic capacitance CP1 and is coupled to a first ground connection or reference node 132. Inductor LF1 has one end coupled to the bottom plate 128b of capacitor C1 and has another end coupled to the ground connection 132. When a part of the isolation and resonance circuitry 122a, the capacitor CF1 has one plate coupled to the bottom plate 128b of capacitor C1 and has another plate coupled to the ground connection 132.

Isolation and resonance circuitry 122b includes a coupling or isolation capacitor C2, a substrate element SE2, and a coil that is illustrated as a filter inductor LF2. In an alternative example, the isolation and resonance circuitry 122b includes LF2 and also includes a filter capacitor CF2 coupled together in parallel. In a further example, the coil is implemented as a transformer instead of the inductor LF2, with or without the inclusion of CF2. In yet another example, LF2 is implemented as a transmission line, with or without the inclusion of CF2. Also, in some examples, the circuitry 122a and 122b can be matched or substantially identical. In other examples, the circuitry 122a and 122b can be different.

The capacitor C2 includes a conductive element referred to as a top plate 136t and a conductive element referred to as a bottom plate 136b. The bottom plate 136b of capacitor C2 has an associated parasitic capacitance CP2, and the top plate 136t is electrically isolated from the bottom plate 136b of capacitor C2.

As illustrated, the top plate 136t of capacitor C2 is coupled to the other end of the interconnect 134, and the bottom plate 136b of capacitor C2 is coupled to a node 138. Node 138 may represent a connection to other circuitry outside of the system 120, such as a receive circuit for receiving a data signal. Substrate element SE2 is coupled to the bottom plate 136b of capacitor C2 by parasitic capacitance CP2 and is coupled to a second ground connection or reference node 140. Inductor LF2 has one end coupled to the bottom plate 136b of capacitor C2 and has another end coupled to the ground connection 140. When a part of the isolation and resonance circuitry 122b, the capacitor CF2 has one plate coupled to the bottom plate 136b of capacitor C2 and has another plate coupled to the ground connection 140.

A line 150 indicates separation of two different power domains having different power supplies (not shown) and different ground connections 132, 140. In an example, the power domain to the left of line 150 provides a relatively lower voltage power supply, for instance less than 10 volts. The power domain to the right of line 150 provides a relatively higher voltage power supply, for instance over 100 volts. However, the power supply values may differ in other examples.

As illustrated, capacitors C1 and C2 form an isolation circuit 130 that provides electrical isolation, and in particular a galvanic isolation barrier, while further providing for capacitive coupling of a data signal between the two power domains. A resonant circuit 124a is formed by LF1 and parasitic capacitance CP1 (and capacitor CF1 if used in the circuit 124a). A resonant circuit 124b is formed by LF2 and parasitic capacitance CP2 (and capacitor CF2 if used in the circuit 124b). Resonant circuits 124a and 124b are designed and constructed to resonate at a resonance frequency at or near a carrier frequency for the data signal being coupled across the galvanic isolation barrier. In another example, system 120 does not include LF1, CF1, LF2, and CF2.

The isolation system 120 may be implemented on one or more semiconductor dies or integrated circuit chips, also referred to herein as ICs or IC chips. In one example, the isolation system 120 is part of a single IC. In another example, isolation and resonance circuitry 122a is a part of one IC and isolation and resonance circuitry 122b is a part of a different IC. In another example, circuitry 146 that includes the isolation circuit 130, the parasitic capacitances CP1 and CP2, and the substrate elements SE1 and SE2 are a part of one IC; a second IC includes the inductor LF1 (and capacitor CF1 if used in the circuit); and a third IC includes the inductor LF2 (and capacitor CF2 if used in the circuit). In examples, wherein system 120 does not include the resonant circuits 124a and 124b, the circuit 146 may be a part of a single IC. Alternatively, isolation capacitor C1 (and associated parasitic capacitance CP1) and substrate element SE1 are a part of one IC, and isolation capacitor C2 (and associated parasitic capacitance CP2) and substrate element SE2 are a part of another IC.

During operation of a system or module that includes the isolation system 120, a data input signal DIN having digital data modulated onto a carrier may be received at an input 142 of the system 120. Input 142 is coupled to node 126. The system 120 creates a channel or conduit at the carrier frequency. This channel is used to capacitively couple the data across the galvanic isolation barrier and to generate a data output signal DOUT carrying the data at the carrier frequency. DOUT is generated at an output 144 of the system 120. Output 144 is coupled to node 138.

A challenge is constructing the channel to mitigate energy loss within the channel over a wide range of frequencies. One source of energy loss is the parasitic capacitances CP1 and CP2, wherein the extent of the energy loss depends on a quality factor, Q, associated with each parasitic capacitance. Namely, Q represents the performance efficiency of a given capacitor or effective capacitor, such as a parasitic capacitance. Namely, the higher the Q, the lower the energy loss. Q for a capacitor can be expressed by the following equation:

Q=1/(R_{EQ}Cω), (1)

where R_{EQ} is an equivalent series resistance associated with the capacitor; C is the capacitance value; and ω is resonance frequency.

In accordance with equation (1), Q (and hence performance efficiency) decreases as the resonance frequency increases for a given parasitic capacitance CP1 or CP2 within the isolation system 120. Thus, constructing the channel with a higher or improved Q for the parasitic capacitances CP1 and CP2 could mitigate energy loss within the channel at higher resonance and carrier frequencies. Inclusion of the substrate elements SE1 and SE2 within the isolation system 120, in accordance with one or more examples of this description, improves the Q for the parasitic capacitances CP1 and CP2, respectively. More particularly, including the substrate elements SE1 and SE2 improves the Q by decreasing the respective equivalent series resistance associated with the parasitic capacitances CP1 and CP2.

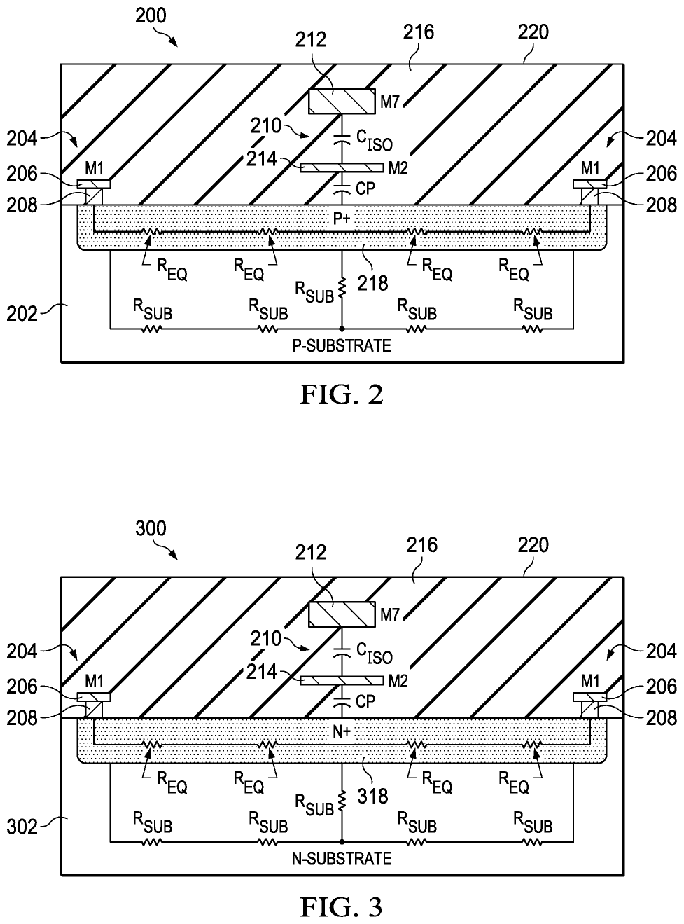

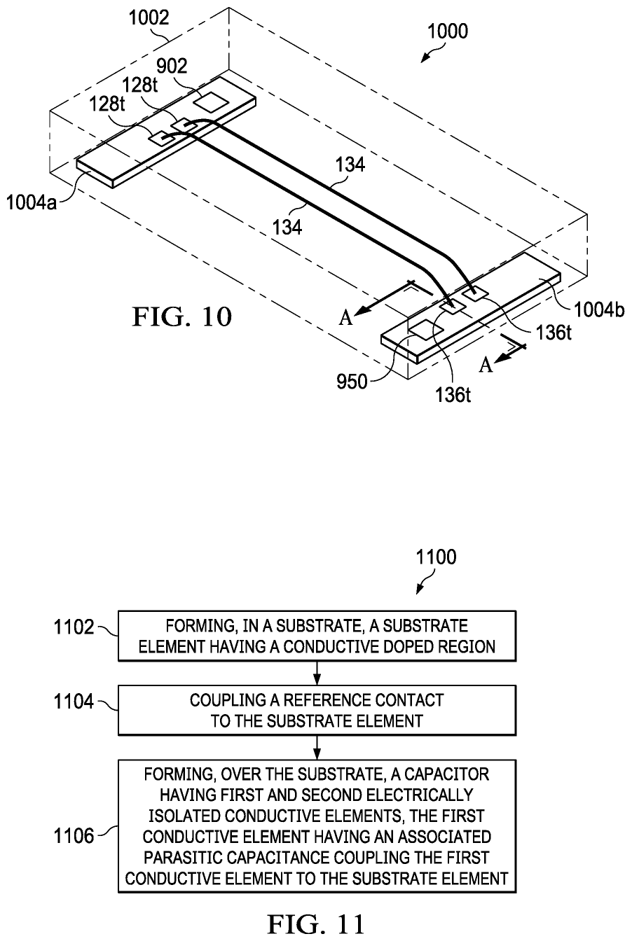

FIGS. 2-5 each illustrate example IC portions having a coupling capacitor, a parasitic capacitance associated with a conductive element (e.g., the bottom plate) of the coupling capacitor, and a substrate element constructed to improve the Q associated with the parasitic capacitance. Some examples according to this description may improve the Q associated with the parasitic capacitance without impacting the isolation rating of the coupling capacitor. In a particular example, the cross-sectional views shown in FIGS. 2-5 are taken at a line AA shown in FIG. 10.

In one particular example, the components illustrated in each of FIGS. 2-5 are represented by equivalent circuitry capacitor C1, parasitic capacitance CP1, substrate element SE1, and ground connection 132 shown in FIG. 1. Alternatively, the components illustrated in each of FIGS. 2-5 are represented by equivalent circuitry capacitor C2, parasitic capacitance CP2, substrate element SE2, and ground connection 140 shown in FIG. 1. Moreover, although the ICs depicted respectively in FIGS. 2-5 include a single capacitor, parasitic capacitance, and substrate element, multiple of such components may be a part of the same IC. Also, one or more other circuit components may be a part of the ICs depicted in FIGS. 2-5, such as an inductor that may represent inductor LF1 or LF2 shown in FIG. 1, a capacitor that may represent capacitor CF1 or CF2 shown in FIG. 1, or other circuitry such as transistors, oscillators, power amplifiers, envelop detectors, and buffer circuits, some of which are depicted in other figures herein.

Referring to FIG. 2, which is a partial cross-sectional view of an IC 200 having a substrate element 218. The integrated circuit 200 includes a substrate 202, reference contacts 204 coupled to the substrate 202, a capacitor 210 formed over the substrate 202, and the substrate element 218 formed in the substrate 202. A “substrate” means the base material upon which an IC such as the IC 200, is built. Example substrates include wafers, or portions thereof, formed from semiconductor material including, but not limited to, undoped (intrinsic) silicon or uniformly doped (extrinsic) silicon and are, thereby, also referred to as semiconductor substrates. A semiconductor substrate uniformly doped with or having a uniform concentration of n-type dopant atoms such as phosphorus or arsenic is referred to herein as an n-type substrate or an n-substrate. A semiconductor substrate uniformly doped with or having a uniform concentration of p-type dopant atoms such boron is referred to herein as a p-type substrate or a p-substrate. The substrate 202, in this example, is a p-type substrate or p-substrate.

As used herein, a “reference contact” means a structure that is coupled to a substrate and is adapted, for instance through the type of material from which it is made, to be electrically connected to a voltage reference. For instance, the reference contacts 204 are adapted to be electrically connected to a ground connection or reference node, such as ground connections 132 and 140 shown in FIG. 1. As illustrated, each reference contact 204 includes a first portion 206 and a second portion 208. The first portion 206 is formed from a metal layer, for instance a layer of aluminum, formed (e.g., deposited) over the substrate 202. As illustrated, the first portion 206 is formed from a first metal layer (“M1”) deposited over the substrate 202. The second portion 208 is a metallic interconnect, for instance formed from conductive materials such as tungsten, which couples the first portion 206 of the reference contact 204 to the substrate 202.

When integrated in a system, such as a system represented by the isolation system 120, the reference contacts 204 may be coupled to respective pads (not shown) on a surface 220 of the IC 200. The coupling between the reference contacts 204 and the pads may be through metallic interconnects or vias (not shown) formed through and/or between one or more insulating layers 216 of the IC 200. The pads may be further coupled to ground connections, e.g., represented by 132 or 140 of FIG. 1, using interconnects such as bond wires and/or electrical traces, for instance.

The capacitor 210 includes conductive elements 212 and 214, e.g., top and bottom plates respectively, formed over the substrate 202. Due to their construction, conductive elements 212 and 214 may also be referred to as metallic elements. Namely, the conductive elements 212 and 214 are formed in different metal layers, for instance different aluminum layers, formed (e.g., deposited) over the substrate 202 between the one or more insulating layers 216. Accordingly, the one or more insulating layers 216 provide electrical isolation between the conductive elements 212 and 214 of the capacitor 210. The one or more insulating layers 216 may be fabricated using isolations materials, such as silicon oxide (SO), silicon dioxide (SiO₂), silicon carbide, etc., formed, inserted, or layered between the metal layers.

The capacitor 210 is constructed to have a capacitance C_{ISO}, and a parasitic capacitance CP is associated with the conductive element 214. Moreover, R_{EQ} is an equivalent series resistance through the substrate element 218 and associated with CP, which impacts the Q for CP. In one example, CP is at least 5×C_{ISO}. In a particular example, C_{ISO} is in the range of 20-400 femtofarads (fF), and CP is in the range of 100 fF to 2 picofarads. However these capacitances may be different in other examples.

As illustrated, the conductive element 214 is formed in a second metal layer (“M2”), and the conductive element 212 is formed in a seventh metal layer (“M7”). However, in other examples, the conductive elements 212 and 214 may be formed in other metal layers. The particular layers may depend, at least in part, on a total number of metal layers formed above the substrate 202 from which additional electrical components such as transistors (not shown) and interconnections (not shown) may be formed.

During operation and upon receiving a data signal at the conductive element 214 from circuitry in a first power domain, capacitance C_{ISO} capacitively couples the data signal across the isolation barrier provided by the one or more insulating layers 216 and onto the conductive element 212. From the conductive element 212, the data signal may be provided to circuitry in a second power domain. In one example, the data signal is provided from the conductive element (e.g., top plate) 212 of the capacitor 210 to a conductive element (e.g., top plate) of a second coupling capacitor. The data signal is then capacitively coupled across a second isolation barrier onto another conductive element (e.g., bottom plate) of the second coupling capacitor for providing to the circuitry in the second power domain.

The substrate element 218 is constructed to reduce the equivalent series resistance R_{EQ} in order to reduce the amount of the data signal that is shunted from the conductive element 214 through the parasitic capacitance CP to a ground connection. Particularly, the substrate element 218 is constructed as or constructed to include a conductive region formed (e.g., implanted or diffused) in the substrate 202 beneath and coupled to the conductive element 214 and the reference contacts 204, which reduces R_{EQ}. As illustrated, the substrate element 218 is capacitively coupled to the conductive element 214 by the parasitic capacitance CP and is coupled to the reference contacts 204 by a direct mechanical connection that facilitates the electrical connection. As further illustrated, the substrate element 218 spatially overlaps (extends beyond the border of) both the reference contact 204 and the bottom plate 214 of the capacitor 210. Although a full overlapping is shown, in another example the substrate element 218 partially overlaps (extends beyond at least part of the border of) one or both of the reference contacts 204 and the bottom plate 214 of the capacitor 210. The full or partial overlapping aligns a substrate element with one or more reference contacts and with a bottom plate of a capacitor of an integrated circuit.

As used herein, a “conductive region” or “conductive doped region” means a doped region of a substrate that has a lower resistivity than the substrate and a lower resistivity than a well (e.g., n-well or p-well) formed in the substrate. The lower resistivity is achieved by higher doping concentrations in the conductive doped region than in the region (e.g., the substrate or the well) surrounding the conductive doped region.

In this example, the substrate element 218 is a “uniform” doped region, meaning that the substrate element 218 has the same type (e.g., n-type or p-type) of doping and the same or substantially the same concentration of doping throughout the entirety of the substrate element, within the constraints of the fabrication process. Particularly, the substrate element 218 has a uniform p-type doping shown as a p+ doped region. A p+ doped region is a region that is heavily doped with p-type dopant atoms such as boron as compared to the region surrounding the p+ region, in this case the substrate 202.

In one example, a heavily doped region may have 10,000 or more times the doping concentration than the surrounding region, such as where the heavily doped region is formed in a lightly doped area such as the substrate. In another example, the heavily doped region may have 100 to 1,000 times the doping concentration than the surrounding region, such as where the heavily doped region is formed in a moderately doped region such as a well within the substrate. As used herein, a “well” means a doped region within a substrate normally used as a building block for a transistor formed in the substrate. In a particular example, a lightly doped region, such a substrate region, includes 1 impurity (dopant) atom per 10⁷ atoms; a moderately doped region, such a well region, has 1 impurity (dopant) atom per 10⁵ atoms; and a heavily doped region, such a p+ or n+ region, has 1 impurity (dopant) atom per 10³ atoms. However, other relative concentrations may be used for lightly, moderately, and heavily doped regions depending, for instance, on the relative resistances desired for the regions.

In one example, the uniform doped region is a patterned region made as a result of a patterning process, such as photolithography. In another example, the uniform doped region is a non-patterned region resulting from deposition or implantation of doping molecules without any subsequent patterning process being performed on the doped region. In yet another example, the uniform doped region is a silicided region formed by using a silicide formation technique to create an alloy, thereby further increasing the conductivity and, in turn, reducing the equivalent series resistance R_{EQ} of the doped region.

In an example where the substrate element 218 is a uniform p+ doped region that is silicided and non-patterned, the equivalent series resistance R_{EQ} can be over 40× less than the resistance R_{SUB} of the substrate 202. This can result in a Q for the parasitic capacitance CP that is improved by over 40× as compared to the Q for CP without the substrate element 218. When the substrate element 218 is a uniform p+ doped region that is silicided and patterned, this may result in a slightly higher equivalent series resistance R_{EQ} and consequently a slightly lower Q, but with a benefit of a lower parasitic capacitance CP. A lower parasitic capacitance CP allows use of a larger coil (e.g., LF1 or LF2) in the resonant circuit (e.g., 124a or 124b), resulting in lower dissipative losses in the coil.

FIG. 3 is a partial cross-sectional view of another example IC 300 having a substrate element 318. The integrated circuit 300 includes a substrate 302, reference contacts 204 coupled to the substrate 302, a capacitor 210 formed over the substrate 302, and the substrate element 318 formed in the substrate 302. In this example, the reference contacts 204 and capacitor 210 are formed and coupled as described above by reference to the example IC 200 shown in FIG. 2. However, in contrast to the example IC 200 shown in FIG. 2, the substrate 302 is an n-type substrate or n-substrate, and the substrate element 318 has a uniform n-type doping shown as an n+ doped region. An n+ doped region is a region that is heavily doped with n-type dopant atoms such as phosphorus or arsenic as compared to the region surrounding the n+ region, in this case the substrate 302.

In one example, the substrate element 318 is patterned. In another example, the substrate element 318 is non-patterned. In yet another example, the substrate element 318 is silicided. Moreover, IC examples having the substrate element 318 as a n+ doped region may generate a comparable equivalent series resistance R_{EQ} and resultant Q for parasitic capacitance CP as is generated by IC examples having the substrate element 218 as a p+ doped region.

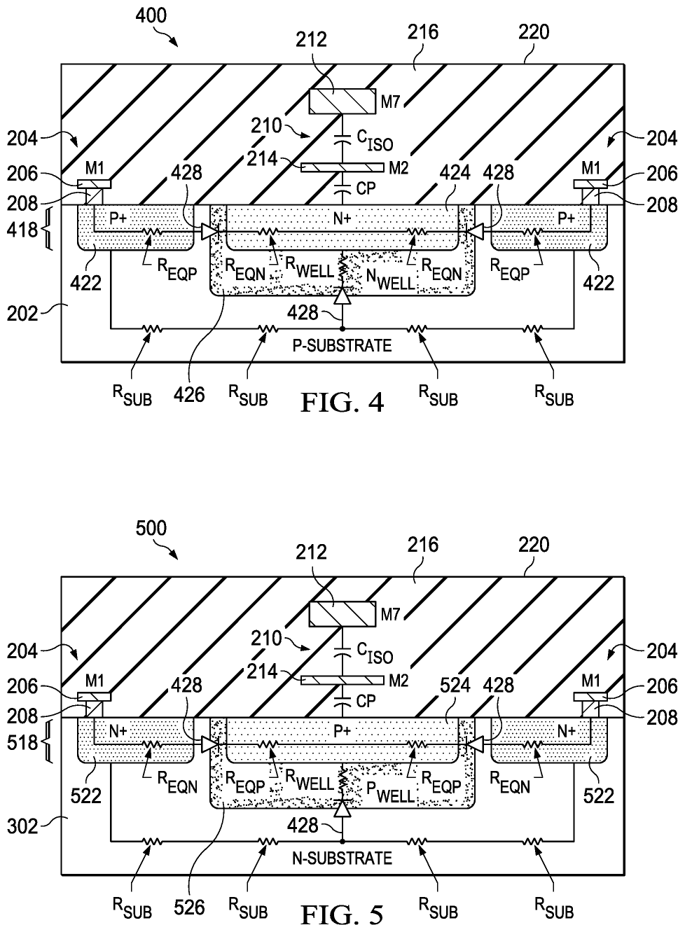

FIG. 4 is a partial cross-sectional view of another example IC 400 having a substrate element 418. The integrated circuit 400 includes a substrate 202, reference contacts 204 coupled to the substrate 202, a capacitor 210 formed over the substrate 202, and the substrate element 418 formed in the substrate 202. In this example, the substrate 202 is a p-substrate, and the reference contacts 204 and capacitor 210 are formed and coupled as described above by reference to the example IC 200 shown in FIG. 2. However in contrast to the example ICs 200 and 300 shown respectively in FIGS. 2 and 3, the substrate element 418 does not have a uniform doped region having a single type of doping. Instead, the substrate element 418 is a conductive region that is non-uniform and, thereby, includes multiple (in this case two) different types of doped regions 422 and 424.

More specifically, as illustrated, the IC 400 also includes an n-well 426 formed (e.g., implanted or diffused) in the substrate 202 beneath and overlapping at least some portion of the conductive element 214. As further illustrated, the border of the n-well 426 extends beyond the border of the conductive element 214. The doped region 424 is a n+ doped region formed within the n-well 426 beneath the conductive element 214. The doped region 422 is a p+ doped region formed in the substrate 202 outside of the n-well 426 and beneath the reference contacts 204. Accordingly, the doped region 424 overlaps the bottom plate 214 of the capacitor 210, and the doped regions 422 overlap the reference contacts 204. Although full overlapping is shown, in another example, the doped region 424 partially overlaps the bottom plate 214 of the capacitor 210, and/or the doped regions 422 partially overlap the reference contacts 204.

In this example, the equivalent series resistance, associated with CP and that impacts the Q for CP, includes both R_{EQN} through the n+ doped region 424 and R_{EQP} through the p+ doped region 424. Also, in this example, the border of the n+ doped region 424 is formed as close to the border of the p+ doped region 422 as is allowable by a semiconductor device fabrication process used to construct or manufacture the IC 400. This reduces or prevents an impact of R_{SUB} and R_{WELL} (the resistance of the n-well 426) on the equivalent series resistance associated with CP. In another example, one or both of the doped regions 422 and 424 of the substrate element 418 is patterned. In another example, one or both of the doped regions 422 and 424 of the substrate element 418 is non-patterned. In yet another example, one or both of the doped regions 422 and 424 of the substrate element 418 is silicided.

In a particular example where the substrate element 418 is silicided and non-patterned, the equivalent series resistance (R_{EQN}+R_{EQP}) can be over 40× less than R_{SUB} and over 30× less than R_{WELL}. This can result in a Q for the parasitic capacitance CP that is improved by over 40× as compared to the Q for CP without the substrate element 418. Patterning one or both of the doped regions 422 or 424 of the substrate element 418 may result in a slightly higher equivalent series resistance (R_{EQN}+R_{EQP}) and consequently a slightly lower Q, but with a benefit of a lower parasitic capacitance CP.

Moreover, IC examples having the substrate element 418 including both a n+ doped region and a p+ doped region may generate a smaller CP and resultant larger Q for CP than is generated by IC examples having the substrate element 218 as a uniform p+ doped region or the substrate element 318 as a uniform n+ doped region. However, a tradeoff of the larger Q is the introduction of diodes 428 into the IC 400, thereby, complicating the substrate network and diminishing predictability during IC design—as compared to other IC examples 200 and 300.

FIG. 5 is a partial cross-sectional view of another example IC 500 having a substrate element 518. The integrated circuit 500 includes a substrate 302, reference contacts 204 coupled to the substrate 302, a capacitor 210 formed over the substrate 302, and the substrate element 518 formed in the substrate 302. In this example, the reference contacts 204 and capacitor 210 are formed and coupled as described above by reference to the example IC 200 shown in FIG. 2, and as also a part of the example IC 300 shown in FIG. 3 and in the example IC 400 shown in FIG. 4.

However, in contrast to the example IC 200 shown in FIG. 2 and the IC example 400 shown in FIG. 4, the substrate 302 is a n-type substrate or n-substrate, as is also a part of the IC example 300 shown in FIG. 3. Moreover, in contrast to the example IC 400 shown in FIG. 4, a p-well 526 is formed in the substrate 302 beneath and overlapping at least some portion of the conductive element 214. As further illustrated, the border of the p-well 526 extends beyond the border of the conductive element 214. Additionally in contrast to the example IC 400 shown in FIG. 4, the substrate element 518 includes a p+ doped region 524 formed within the p-well 526 beneath the conductive element 214. The substrate element 518 further includes a n+ doped region 522 formed in the substrate 302 outside of the p-well 526 and beneath the reference contacts 204. Accordingly, the doped region 524 overlaps the bottom plate 214 of the capacitor 210, and the doped regions 522 overlap the reference contacts 204. Although full overlapping is shown, in another example, the doped region 424 partially overlaps the bottom plate 214 of the capacitor 210, and/or the doped regions 522 partially overlap the reference contacts 204.

In one example, one or both of the doped regions 522 and 524 of the substrate element 518 is patterned. In another example, one or both of the doped regions 522 and 524 of the substrate element 518 is non-patterned. In yet another example, one or both of the doped regions 522 and 524 of the substrate element 518 is silicided. Moreover, IC examples having the substrate element 518 as shown in FIG. 5 may generate a comparable equivalent series resistance (R_{EQN}+R_{EQP}) and resultant Q for parasitic capacitance CP as is generated by IC examples having the substrate element 418 as shown in FIG. 4.

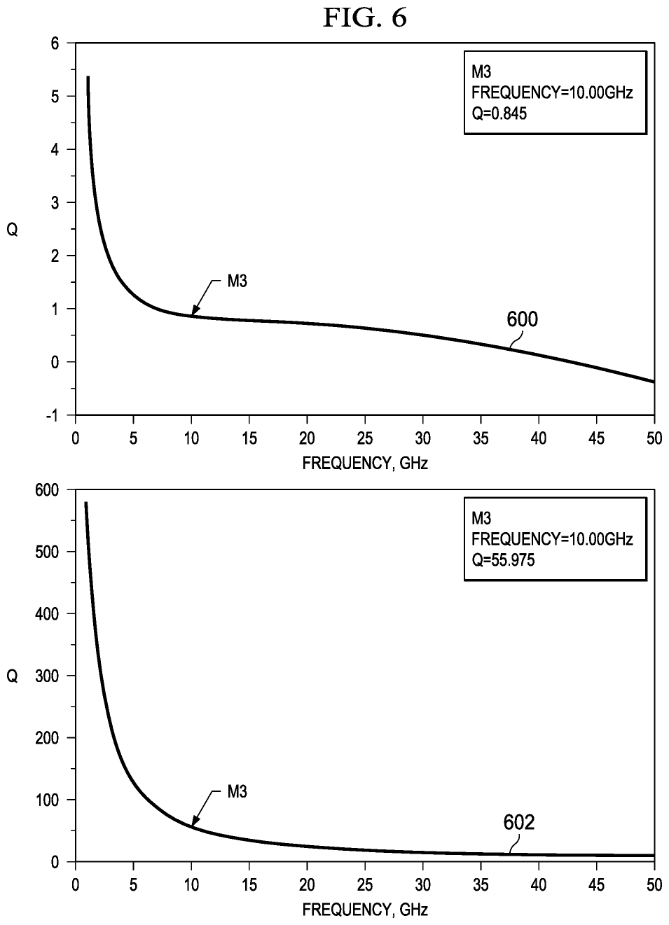

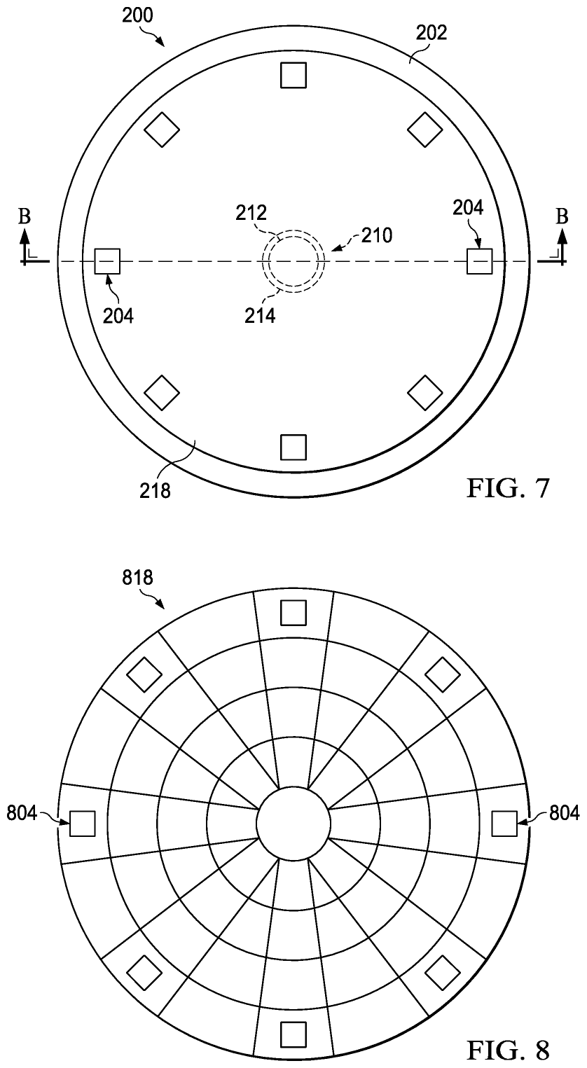

FIG. 6 is a graphical representation illustrating the quality factor for a parasitic capacitance, which is improved by including a substrate element according to one or more examples of this description. Particularly, FIG. 6 illustrates line graphs 600 and 602, each of which represents a change in Q for parasitic capacitance CP over a change in resonant frequency, as measured in gigahertz (“GHz”). However, line graph 600 represents the change in Q for the parasitic capacitance CP when IC circuitry omits a substrate element. Whereas, line graph 602 represents the change in Q for the parasitic capacitance CP when a substrate element is part of the circuitry of the IC.

With further reference to FIG. 6, where one or more ICs incorporates the isolation system 120, the line graph 602 represents the change in Q measured for CP1 where the capacitor C1 and the substrate element SE1 is implemented as shown in FIG. 4. Graph 600 represents the change in Q measured for CP1 where the circuitry omits the substrate element SE1. As depicted, Q is larger in graph 602 than in graph 600 for each frequency over the range of frequencies measured. This demonstrates that larger Q values for CP1 can be obtained by including the substrate element SE1. This further demonstrates that including the substrate element SE1 improves performance efficiency for the circuitry in the GHz frequency range.

For example, a point m3 on both line graphs 600 and 602 represents the Q for CP1 measured at a resonant frequency of 10 GHz. When the substrate element SE1 is not a part of the circuitry, the line graph 600 shows that Q=0.845 for the parasitic capacitance CP1. Accordingly, in the absence of the substrate element SE1 and at the frequency of 10 GHz, more than half of the signal energy of DIN that enters the bottom plate 128b of the capacitor C1 is dissipated through CP1 and its associated equivalent series resistance (e.g., R_{EQN}+R_{EQP}) to the ground connection 132 before the data signal is capacitively coupled to the top plate 128t of C1. If signal dissipation occurs through CP2 and its associated equivalent series resistance (e.g., R_{EQN}+R_{EQP}) to the ground connection 140, this translates to at least a 6 decibel (“dB”) additional loss of power between DIN and DOUT. By contrast, when the substrate element SE1 is a part of the circuitry, the line graph 602 shows that the Q=55.975 for parasitic capacitance CP1. This represents significantly less added power loss between DIN and DOUT close to 0 dB.

FIG. 7 is a partial plan view of the example IC 200 of FIG. 2. Particularly, the cross-sectional view shown in FIG. 2 is taken at a line BB shown in FIG. 7. The plan view shows the substrate 202, eight reference contacts 204 (two of which are labeled) coupled to the substrate 202, the capacitor 210 formed over the substrate 202, and the substrate element 218 formed in the substrate 202 beneath the conductive element 214. The conductive elements 212 and 214 of the capacitor 210 are shown as transparent to illustrate the substrate element 218 being a non-patterned region. In an alternative example, FIG. 8 is a partial plan view of a substrate element 818 that is or includes a patterned region having eight reference contacts 804 (two of which are labeled) coupled thereto. Although eight reference contacts are shown in each of FIGS. 7 and 8, more or fewer reference contacts can be a part of an IC. Also, the patterning can be different than what is illustrated in FIG. 8.

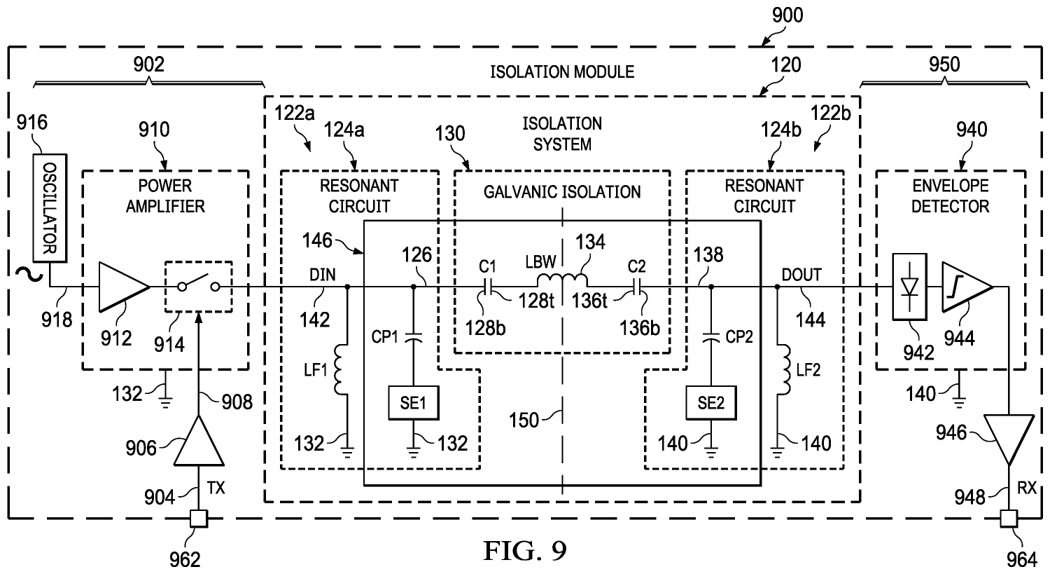

FIG. 9 is a schematic diagram of an isolation module 900 incorporating the isolation system 120 of FIG. 1. Isolation module 900 includes an input terminal 962 and an output terminal 964. The input terminal 962 receives a transmit input signal TX from an external signal source (not shown). The output terminal 964 provides or delivers a receive data signal RX to an external destination circuit (not shown). In practice, the external signal source and the destination circuit can be powered from separate power domains. The isolation module 900 provides galvanic isolation to transmit a digital data from the input terminal 962 to the output terminal 964 across an isolation barrier separating the two power domains.

In the illustrated example, the isolation module 900 includes a transmit circuit 902, a receive circuit 950, and the isolation system 120 coupled between the transmit circuit 902 and the receive circuit 950. The transmit circuit 902 includes an input 904 coupled to the input terminal 962 to receive the transmit input signal TX. The receive circuit 950 includes an output 948 coupled to the output terminal 964 to provide the receive data signal RX. In operation, the isolation system 120 conveys the input data signal DIN from the transmit circuit 902 across a galvanic isolation barrier to the receive circuit 950 as the data output signal DOUT. Moreover in this example, the transmit circuit 902 is powered by a first power domain having the ground connection 132. The receive circuit 950 is separately powered by a second power domain relative to the ground connection 140.

As further illustrated, the transmit circuit 902 includes a buffer amplifier 906, an oscillator 916, and a power amplifier circuit 910. The buffer amplifier 906 receives the TX signal from the input 904. The buffer amplifier 906 can be any suitable single ended or differential amplifier circuit, and can provide electrostatic discharge (ESD) protection in certain embodiments. The buffer amplifier 906 includes an output 908 that provides a data signal to modulate a carrier signal in the power amplifier circuit 910.

The power amplifier circuit 910 includes an amplifier 912 and a switching circuit 914. The oscillator 916 includes an output 918 that provides a carrier signal to the power amplifier circuit 910. In one implementation, the carrier signal is a high-frequency sinusoidal signal in the GHz frequency range. The output of the amplifier 912 is modulated by the switching circuit 914 according to the data signal from the buffer amplifier 906 to provide the data input signal DIN to the input 142 of the isolation system 120. In one example, the power amplifier circuit 910 provides the data input signal DIN as a sinusoidal signal with a non-zero amplitude when the TX signal is in a first binary state (e.g., high or “1”). In this example, the data input signal DIN has a fixed amplitude (e.g., 0 V) when the transmit signal TX is in a second binary state (e.g., low or “0”).

The receive circuit 950 receives the data output signal DOUT from the output 144 of the isolation system 120. The receive circuit 950 includes an envelope detector circuit 940 and an ESD protection/buffer circuit 946. The envelope detector circuit 940 includes a rectifier circuit 942 and a comparator circuit 944. In practice, a time varying signal DOUT is received, having non-zero voltage components or transients responsive to polarity changes in the data input signal DIN as a result of the AC coupling by the series-connected coupling capacitors C1 and C2. The rectifier circuit 942 rectifies the received voltage signal to create a DC voltage signal that is compared with a threshold by the comparator circuit 944. In this example, since the data input signal DIN has a non-zero amplitude for binary “1” transmit data and a zero amplitude for binary “0” transmit data, the output of the comparator 944 will be in a first binary state (e.g., high or “1”) when the rectifier 942 output signal exceeds the threshold voltage. Otherwise, the output of the comparator 944 will be in a second binary state (e.g., low or “0”).

The ESD protection/buffer circuit 946 receives the output signal from the comparator 944 and provides the receive data signal RX at the output node 948. In this manner, the isolation module 900 provides the receive data signal RX corresponding to the received transmit data signal TX, and the RX and TX signals are galvanically isolated from one another via the galvanic isolation circuit 130. Moreover, including the substrate elements SE1 and SE2 in the isolation module 900 allows the coupling of DIN across the galvanic isolation barrier at higher carrier frequencies than is possible without the substrate elements SE1 and SE2, including DIN signals in the 10-20 GHz frequency range and higher.

The isolation module 900 may be implemented in one or more ICs. In one example, the isolation module 900 is a part of a single IC. In another example, isolation and resonance circuitry 122a and transmit circuit 902 is a part of one IC, and isolation and resonance circuitry 122b and receive circuit 950 is a part of a different IC. In another example, circuitry 146 that includes the isolation circuit 130, the parasitic capacitances CP1 and CP2, and the substrate elements SE1 and SE2 are a part of one IC; a second IC includes the transmit circuit 902 and may include the inductor LF1; and a third IC includes the receive circuit 950 and may include the inductor LF2.

FIG. 10 is a perspective view of a system 1000 incorporating the isolation module 900 of FIG. 9 into an example practical implementation. In this example, the isolation module 900 is implemented as a differential circuit, with an IC chip 1004a and an IC chip 1004b. IC chips 1004a and 1004b are collectively referred to herein as IC chips 1004.

IC chip 1004a includes the above-described transmit circuit 902, coupling capacitors C1, and isolation and resonance circuitry 122a. IC chip 1004b includes the receive circuit 950, coupling capacitors C2, and isolation and resonant circuitry 124b. As illustrated, top plates 128t of coupling capacitors C1 are exposed at a top side of the IC chip 1004a to allow wire bonding via interconnects 134 for connection to top plates 136t of coupling capacitors C2 that are exposed at a top side of the IC chip 1004a.

In another example, the isolation module 900 is implemented as a single-ended circuit having one coupling capacitor C1 on the IC chip 1004a and one coupling capacitor C2 on the IC chip 1004b. In another example isolation module 900, the IC chip 1004a does not include the transmit circuit 902, and the IC chip 1004b does not include the receive circuit 950. In other examples, the isolation module 900 is a part of a single IC chip 1004, wherein the interconnects 134 may be wire bonds or traces. The module 900 a part of the single IC chip 1004 may be single ended or differential and may or may not include the transmit circuit 902 and the receive circuit 950.

Moreover, in this example, the parasitic capacitances CP1 associated with the bottom plates 128b of capacitors C1 are effectively part of the IC 1004a along with substrate elements SE1. Also, the parasitic capacitances CP2 associated with the bottom plates 136b of capacitors C2 are effectively part of the IC 1004b along with substrate elements SE2. In this regard, in one example, the respective inductors LF1 and LF2 of the resonant circuits 124a, 124b are fabricated on or in the associated IC chips 1004. In another example, the inductors LF1 and LF2 are separate components electrically connected to the IC chips 1004. Similarly, any capacitors of the resonant circuits 124a, 124b, e.g., CF1 and CF2, can be formed on or in the associated ICs 1004, or can be separate components electrically connected therewith.

FIG. 11 is a flowchart including blocks 1102-1106 depicting an example method 1100 for making an integrated circuit having a substrate element according to one or more examples of this description. The method 1100 may be performed as part of a semiconductor device fabrication process for manufacturing ICs. However, blocks 1102-1106 need not be performed in the semiconductor device fabrication process in the order illustrated in the flowchart.

Block 1102 of method 1100 depicts forming, in a substrate, a substrate element having a conductive doped region. In this example, forming the substrate element occurs during FEOL processing within the semiconductor device fabrication process. The substrate may be a p-type substrate or an n-type substrate. The conductive doped region may include one or more n+ or p+ doped regions.

In one example, the conductive doped region includes a uniform doped region that is a p+ doped region formed in a p-type substrate, for instance as shown in FIG. 2. In another example, the conductive doped region includes a uniform doped region that is a n+ doped region formed in a n-type substrate, for instance as shown in FIG. 3. In yet another example, the conductive doped region includes first and second doped regions having different doping types, for instance as shown in FIGS. 4 and 5. Further to this example, a well is formed in the substrate. The first doped region is formed in the well, and the second doped region is formed outside of the well.

Block 1104 of method 1100 depicts coupling a reference contact to the substrate element. For example, when the substrate element includes a uniform doped region formed in the substrate, the reference contact is coupled near an outer border of the uniform doped region. In another example, wherein the substrate element includes two doped regions, one of which is formed in a well formed in the substrate, the reference contact is coupled near an outer border of the doped region that is formed external to the well.

Block 1106 of method 1100 depicts forming, over the substrate, a capacitor having first and second electrically isolated conductive elements. The first conductive element has an associated parasitic capacitance coupling the first conductive element to the substrate element. For example, when the substrate element includes a uniform doped region formed in the substrate, a center of the first conductive element is formed over a center of the substrate element. In another example, wherein the substrate element includes two doped regions, one of which is formed in a well formed in the substrate, a center of the well is aligned with a center of the first conductive element. The first conductive element is, thereby, parasitically coupled to the doped region that is formed within the well.

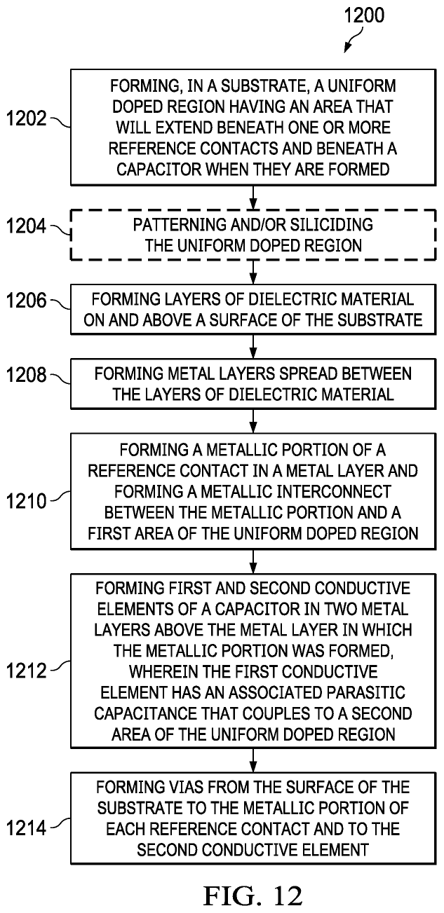

FIG. 12 is a flowchart including blocks 1202-1214 depicting another example method 1200 for making an integrated circuit having a substrate element according to one or more examples of this description. In a particular example, one or more blocks of the method 1200 incorporates or implements one or more blocks of the method 1100. Accordingly, method 1200 may also be performed as part of a semiconductor device fabrication process for manufacturing ICs. However, blocks 1202-1214 need not be performed in the semiconductor device fabrication process in the order illustrated in the flowchart. Moreover, the method 1200 may be used to fabricate the IC portions 200 and 300 shown respectively in FIGS. 2 and 3.

Block 1202 of method 1200 depicts forming, in a substrate, a substrate element having a uniform doped region. The substrate element is formed such that an area of the substrate element will extend beneath both a capacitor and beneath one or more reference contacts that will be formed later in the semiconductor device fabrication process. The substrate element is formed during FEOL processing and includes ion implantation and/or diffusion of dopant atoms into the substrate to generate the uniform doped region.

In one example, n-type dopant atoms or donors, such as phosphorus or arsenic, are used to generate a uniform n+ doped region. In another example, p-type dopant atoms or acceptors, such as boron, are used to generate a uniform p+ doped region. Moreover, the particular dopant atom used, the depth of the doped region, and the density of the dopant atoms within the doped region may be determined, at least in part, based on desired electrical characteristics of the doped region (e.g., desired resistivity), desired CP or Q of the parasitic capacitance, and desired carrier and resonant frequencies during circuit operation.

Block 1204 of method 1200 depicts patterning and/or siliciding the uniform doped region. For instance, determining whether the uniform doped region is patterned and/or silicided may be based, at least in part, on desired electrical characteristics of the doped region (e.g., desired resistivity), desired CP or Q of the parasitic capacitance, and desired carrier and resonant frequencies during circuit operation. For instance, patterning and/or siliciding may be performed at lower frequencies because Q is inherently higher a lower frequencies. Hence, the higher resistivity originating due to the patterning is better tolerated.

Block 1206 of method 1200 depicts forming parallel lateral layers of dielectric material on and above a surface of the substrate, and block 1208 depicts forming parallel lateral metal layers spread between the layers of dielectric material. For example, the layers of dielectric materials and the metal layers are stacked parallel lateral layers on and above a surface of the substrate, from which electrical and other elements and interconnects of the IC may be formed. The layers are stacked such that at least one layer of dielectric material separates each metal layer from each other metal layer. Dielectric materials such as SiO₂ may be used to form oxidation layers, for instance through a deposition process. The deposition process may also be used to form the metal layers using a metal such as aluminum or copper.

As the layers of dielectric material and metal layers are formed, method 1200 includes forming therein reference contacts, a capacitor, and metallic interconnects and vias, as depicted by blocks 1210-1214. More particularly, block 1210 depicts forming, one or more reference contacts, e.g., through patterning and removal processing applied to one or more of the layers of dielectric material and metal layers. Namely, a metallic portion of each reference contact is formed in one of the metal layers over a first area of the uniform doped region. This first area of the uniform doped region may be near an outer border of the uniform doped region. In one example, the metallic portion of the reference contact is formed in a M1 metal layer, which is the initial metal layer deposited closest to the surface of the substrate. Accordingly, metal layers M2, M3, etc. denote the second metal layer, third metal layer, and so on, relative to the surface of the substrate and denote increasingly higher metal layers above metal layer M1.

Moreover, forming each reference contact as depicted in block 1210 includes forming a metallic interconnect between the metallic portion of the reference contact and the first area of the uniform doped region. In an example, forming the metallic contact includes creating an opening in the layer of dielectric deposited between M1 and the surface of the substrate. The opening is created below where the metallic portion of the reference contact will be formed. Metal, such as tungsten, is deposited in the opening to create the metallic interconnect and, thereby, the electrical connection between the metallic portion of the reference contact and the substrate element. In one example, the metallic interconnect is directly mechanically connected between the metallic portion of the reference contact and the substrate element.

Block 1212 of method 1200 depicts forming first and second conductive elements of a capacitor in two metal layers above the metal layer in which the metallic portion of the reference contact was formed. In an example, the first and second conductive elements are formed, e.g., through patterning and removal processing applied to metal layers M1 and M7. However, any two suitable upper metal layers may be used. Moreover, the first and second conductive elements are located over a second area of the uniform doped region. For example, centers of the first and second conductive elements and of the uniform doped region are aligned. The first conductive element is formed closest to the substrate element relative to the second conductive element. Accordingly, a parasitic capacitance of the first conductive element couples the first conductive element to the second area of the uniform doped region. The first and second conductive elements may be the same or a different size.

Block 1214 of method 1200 depicts forming electrical connections or vias from the metallic portion of each reference contact and from the second conductive element of the capacitor to the surface of the substrate. Namely, openings are formed from the surface of the substrate to the metallic portion of each reference contact and to the second conductive element. Metal is deposited in the openings, and a metallic pad is formed on the surface of the substrate over each opening to complete the respective vias.

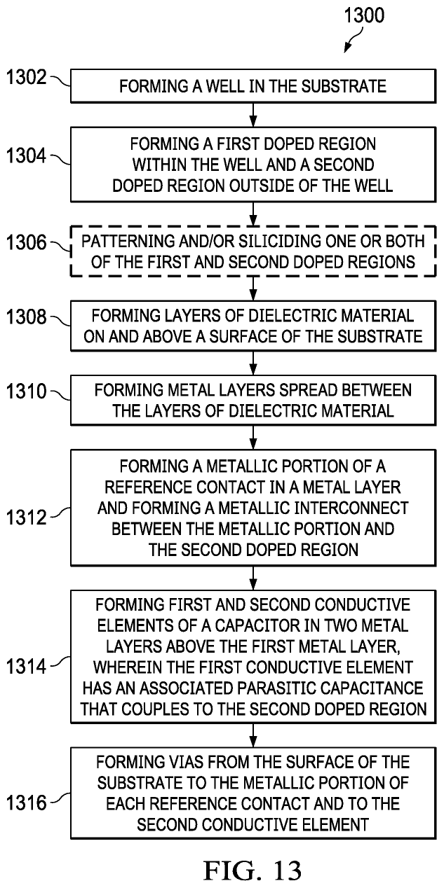

FIG. 13 is a flowchart including blocks 1302-1316 depicting another example method 1300 for making an integrated circuit having a substrate element according to one or more examples of the this description. In a particular example, one or more blocks of the method 1300 incorporates or implements one or more blocks of the method 1100. Also, as will be seen, some of the blocks 1302-1316 indicate similar processing as described with respect to corresponding ones of the blocks 1202-1214 of method 1200. Thus, method 1300 may also be performed as part of a semiconductor device fabrication process for manufacturing ICs. However, blocks 1302-1316 need not be performed in the semiconductor device fabrication process in the order illustrated in the flowchart. Moreover, the method 1300 may be used to fabricate the IC portions 400 and 500 shown respectively in FIGS. 4 and 5.

Blocks 1302 and 1304 of method 1300 collectively depict forming, in a substrate, a substrate element having multiple doped regions, for example first and second doped regions. Namely, block 1302 depicts forming a well within the substrate, for instance through ion deposition and diffusion; and method 1304 depicts forming the first doped region within the well and forming the second doped region outside of the well. The substrate element is formed such the first doped region will be located beneath a capacitor, and the second doped region will be located beneath one or more reference contacts that will be formed later in the semiconductor device fabrication process. Moreover, in an example, an outer boundary of the first doped region is formed as close as the semiconductor device fabrication processing allows to an outer boundary of the second doped region.

The substrate element is formed during FEOL processing and includes ion implantation and/or diffusion of dopant atoms into the substrate to generate the first and second doped regions each having different dopant types. In an example, when the first doped region is a n+ doped region, the second doped region is a p+ doped region. In another example, when the first doped region is a p+ doped region, the second doped region is a n+ doped region. Moreover, the particular dopant atom used, the depth of the doped regions and the well, and the density of the dopant atoms within the doped regions may be determined, at least in part, based on desired electrical characteristics of the doped region (e.g., desired resistivity), desired CP or Q of the parasitic capacitance, and desired carrier and resonant frequencies during circuit operation.

Block 1306 of method 1300 depicts patterning and/or siliciding one or both of the doped regions. Determining whether one or both of the doped regions is patterned and/or silicided may be based, at least in part, on one or more of the factors described above by reference to block 1204 of method 1200. Moreover, in an example, blocks 1308 and 1310 of method 1300 depict forming parallel lateral layers of dielectric material and metal layers as described above by reference to respective blocks 1206 and 1208 of method 1200.

As the layers of dielectric material and metal layers are formed, method 1300 includes forming therein reference contacts, a capacitor, and metallic interconnects and vias, as depicted by blocks 1312-1316. More particularly, block 1312 depicts forming, one or more reference contacts, e.g., through patterning and removal processing applied to one or more of the layers of dielectric material and metal layers. Namely, a metallic portion of each reference contact is formed in one of the metal layers, e.g., metal layer M1, over the second doped region. Moreover, forming each reference contact as depicted in block 1312 includes forming a metallic interconnect between the metallic portion of the reference contact and the second doped region.

Block 1314 of method 1300 depicts forming first and second conductive elements of a capacitor in two metal layers, e.g., metal layers M2 and M7, above the metal layer in which the metallic portion of the reference contact was formed. The first and second conductive elements are located over the first doped region. For example, centers of the first and second conductive elements and of the first doped region are aligned. The first conductive element is formed closest to the substrate element relative to the second conductive element. Accordingly, a parasitic capacitance of the first conductive element couples the first conductive element to the first doped region. The first and second conductive elements may be the same or a different size.

Block 1316 of method 1300 depicts forming electrical connections or vias from the metallic portion of each reference contact and from the second conductive element of the capacitor to the surface of the substrate. In an example, the vias are formed using processing described by reference to block 1214 of method 1200.

Modifications are possible in the described embodiments, and other embodiments are possible, within the scope of the claims.

What is claimed is:

1. An integrated circuit comprising:
a substrate;
a reference contact coupled to the substrate;
a capacitor over the substrate and including:
a first conductive element having an associated parasitic capacitance; and
a second conductive element electrically isolated from the first conductive element; and
a substrate element coupled to the first conductive element by the parasitic capacitance and coupled to the reference contact, wherein the substrate element includes a conductive doped region in the substrate and aligned with the first conductive element and the reference contact.

2. The integrated circuit of claim 1, wherein the conductive doped region includes a single uniform doped region aligned with both the first conductive element and the reference contact.

3. The integrated circuit of claim 2, wherein the substrate is a p-type substrate, and the uniform doped region is a p+ doped region.

4. The integrated circuit of claim 2, wherein the substrate is a n-type substrate, and the uniform doped region is a n+ doped region.

5. The integrated circuit of claim 1, wherein the substrate includes a well aligned with the first conductive element, and the conductive doped region includes:
a first doped region within the well and aligned with the first conductive element; and
a second doped region outside the well and aligned with the reference contact.

6. The integrated circuit of claim 5, wherein the substrate is a p-type substrate, the well is an n-well, the first doped region is an n+ doped region, and the second doped region is a p+ doped region.

7. The integrated circuit of claim 5, wherein the substrate is an n-type substrate, the well is a p-well, the first doped region is a p+ doped region, and the second doped region is an n+ doped region.

8. The integrated circuit of claim 1, wherein the conductive doped region includes a silicided region.

9. The integrated circuit of claim 1, wherein the conductive doped region includes a non-patterned region.

10. The integrated circuit of claim 1 wherein the conductive doped region includes a patterned region.

11. A system comprising:
isolation circuitry including:
a semiconductor substrate;
a reference contact coupled to the semiconductor substrate;
an isolation capacitor over the semiconductor substrate and including:
a first conductive element having an associated parasitic capacitance; and
a second conductive element galvanically isolated from the first conductive element; and
a conductive doped region in the semiconductor substrate, wherein the conductive doped region is aligned with the first conductive element and the reference contact.

12. The system of claim 11, wherein the isolation circuitry is first isolation circuitry comprising a first semiconductor substrate, a first reference contact, a first isolation capacitor, and a first conductive doped region, and the system further comprising:
second isolation circuitry electrically connected to the first isolation circuitry and including:
a second semiconductor substrate;
a second reference contact coupled to the second semiconductor substrate;
a second isolation capacitor over the second semiconductor substrate and including:
a third conductive element having an associated second parasitic capacitance; and
a fourth conductive element galvanically isolated from the third conductive element; and
a second conductive doped region in the second semiconductor substrate,
wherein the second conductive doped region is aligned with the third conductive element and the second reference contact; and
wherein the first isolation circuitry is integral with a first integrated circuit, and the second isolation circuitry is integral with a second integrated circuit.

13. The system of claim 11, wherein the isolation circuitry is first isolation circuitry comprising the semiconductor substrate, a first reference contact, a first isolation capacitor, and a first conductive doped region, and the isolation system further comprising:
second isolation circuitry electrically connected to the first isolation circuitry and including:
the semiconductor substrate;
a second reference contact coupled to the semiconductor substrate;
a second isolation capacitor over the semiconductor substrate and including:
a third conductive element having an associated second parasitic capacitance; and
a fourth conductive element galvanically isolated from the third conductive element;
a second conductive doped region in the semiconductor substrate, wherein the second conductive doped region is aligned with the third conductive element and the second reference contact; and
wherein the first isolation circuitry and the second isolation circuitry are integral with the same integrated circuit.

14. The system of claim 13, wherein the first isolation circuitry and the second isolation circuitry is integral with a first integrated circuit, the system further comprising:
a second integrated circuit including transmit circuitry coupled to the second conductive element of the first isolation capacitor; and
a third integrated circuit including receive circuitry coupled to the fourth conductive element of the second isolation capacitor.

15. The system of claim 11, wherein the semiconductor substrate is a p-type substrate, and the conductive doped region includes a single uniform p+ doped region aligned with both the first conductive element and the reference contact.

16. The system of claim 11, wherein the semiconductor substrate is an n-type substrate, and the conductive doped region includes a single uniform n+ doped region aligned with both the first conductive element and the reference contact.

17. The system of claim 11, wherein the semiconductor substrate is a p-type substrate including an n-well aligned with the first conductive element, and the conductive doped region includes:
an n+ doped region within the n-well and aligned with the first conductive element; and
a p+ doped region outside the n-well and aligned with the reference contact.

18. The system of claim 11, wherein the semiconductor substrate is an n-type substrate including a p-well aligned with the first conductive element, and the conductive doped region includes:
a p+ doped region within the p-well and aligned with the first conductive element; and
an n+ doped region outside the p-well and aligned with the reference contact.

19. A method of making an integrated circuit, the method comprising:
forming, in a substrate, a substrate element having a conductive doped region;
forming, on the substrate, a reference contact that is aligned with and mechanically coupled to the substrate element; and
forming, over the substrate and aligned with the conductive doped region, a capacitor having first and second electrically isolated conductive elements, the first conductive element having an associated parasitic capacitance.

20. The method of claim 19, wherein the conductive doped region includes a single uniform doped region overlapping both the reference contact and the first conductive element.

21. The method of claim 19, wherein the conductive doped region includes a first doped region and a second doped region, and forming the substrate element includes:
forming a well in the substrate, wherein the first conductive element is formed above the well;
forming the first doped region within the well; and
forming the second doped region outside of the well, wherein the reference contact is aligned with and mechanically coupled to the second doped region.
